(19) United States
(12) Patent Application Publication
(10) Pub. No.: US 2022/0350236 A1
(43) Pub. Date: Nov. 3, 2022

(54) EXTREME ULTRAVIOLET MASK AND METHOD OF MANUFACTURING THE SAME

(71) Applicant: TAIWAN SEMICONDUCTOR MANUFACTURING COMPANY, LTD., Hsinchu (TW)

(72) Inventors: Minfeng CHEN, Hsinchu City (TW); Shuo-Yen CHOU, Hualien County (TW)

(21) Appl. No.: 17/865,294

(22) Filed: Jul. 14, 2022

Related U.S. Application Data
(62) Division of application No. 16/520,210, filed on Jul. 23, 2019.
(60) Provisional application No. 62/712,728, filed on Jul. 31, 2018.

(51) Int. Cl. G03F 1/24

(52) U.S. Cl. CPC G03F 1/24; B82Y 40/00

(57) ABSTRACT

An extreme ultraviolet mask, comprising an absorber having an index of refraction ranging from 0.87 to 1.02, an extinction coefficient ranging from 0.065 to 0.085, and a thickness ranging from 33.5 nm to 43.5 nm.

### CROSS-REFERENCE TO RELATED APPLICATIONS

This application is a Divisional Application of U.S. application Ser. No. 16/520,210, filed Jul. 23, 2019, which claims priority to U.S. Provisional Patent Application No. 62/712,728, filed Jul. 31, 2018, the entire disclosures of each of which are incorporated herein by reference.

### BACKGROUND

As consumer devices have gotten smaller and smaller in response to consumer demand, the individual components of these devices have necessarily decreased in size as well. Semiconductor devices, which make up a major component of devices such as mobile phones, computer tablets, and the like, have been pressured to become smaller and smaller, with a corresponding pressure on the individual devices (e.g., transistors, resistors, capacitors, etc.) within the semiconductor devices to also be reduced in size. The decrease in size of devices has been met with advancements in semiconductor manufacturing techniques such as lithography.

For example, the wavelength of radiation used for lithography has decreased from ultraviolet to deep ultraviolet (DUV) and, more recently to extreme ultraviolet (EUV). Further decreases in component size require further improvements in resolution of lithography which are achievable using extreme ultraviolet lithography (EUVL). EUVL employs radiation having a wavelength of about 1-100 nm.

As the semiconductor industry has progressed into nanometer technology process nodes in pursuit of higher device density, higher performance, and lower costs, there have been challenges in reducing semiconductor feature size.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 shows an extreme ultraviolet lithography tool according to an embodiment of the disclosure.

FIG. 2 shows a schematic diagram of a detail of an extreme ultraviolet lithography tool according to an embodiment of the disclosure.

FIG. 3 is a cross-sectional view of a reflective mask according to embodiments of the disclosure.

FIG. 4 is a graph showing the reflectivity versus the normalized horizontal pattern best focus shift according to embodiments of the disclosure.

FIG. 5 is a graph showing the reflectivity versus the normalized vertical pattern best focus shift according to embodiments of the disclosure.

FIG. 6 is a graph showing a simulation of the absorber thickness versus absorber reflectivity at different extinction coefficients according to embodiments of the disclosure.

FIG. 7 is a graph showing a simulation of the pattern pitch versus the best focus for various examples according to the present disclosure.

FIG. 8 is a graph showing a simulation of the pattern pitch versus the individual depth of focus for various examples according to the present disclosure.

FIG. 9 is a graph showing a simulation of the pattern pitch versus the image log slope for various examples according to the present disclosure.

FIG. 10 is a graph showing a simulation of the pattern pitch versus the horizontal-vertical bias for various examples according to the present disclosure.

FIG. 11 is a flowchart illustrating a method of manufacturing an extreme ultraviolet mask according to an embodiment of the disclosure.

FIG. 12 is a flowchart illustrating a method of optimizing an absorption layer for an extreme ultraviolet mask according to an embodiment of the disclosure.

FIG. 13 is a flowchart illustrating a method of manufacturing a semiconductor device according to an embodiment of the disclosure.

FIGS. 14A, 14B, and 14C illustrate the results of a simulation for optimizing the reflectivity of an EUV mask according to an embodiment of the disclosure.

FIGS. 15A and 15B illustrate a simulation for optimizing the reflectivity of an EUV mask according to an embodiment of the disclosure.

FIGS. 16A, 16B, 16C, 16D, 16E, 16F, 16G, and 16H show simulated optimization results of an EUV mask for vertically oriented patterns according to an embodiment of the disclosure.

FIGS. 17A, 17B, 17C, 17D, 17E, 17F, 17G, and 17H show simulated optimization results of an EUV mask for vertically oriented patterns according to an embodiment of the disclosure.

### DETAILED DESCRIPTION

It is to be understood that the following disclosure provides many different embodiments, or examples, for implementing different features of the disclosure. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.”

The present disclosure is generally related to extreme ultraviolet (EUV) lithography masks and methods. In an EUVL tool, a laser-produced plasma (LPP) generates extreme ultraviolet radiation which is used to image a photoresist-coated substrate. In an EUV tool, an excitation laser heats metal (e.g., tin, lithium, etc.) target droplets in the LPP chamber to ionize the droplets to plasma, which emits the EUV radiation. For reproducible generation of EUV radiation, the target droplets arriving at the focal point (also referred to herein as the “zone of excitation”) have to be substantially the same size and arrive at the zone of excitation at the same time as an excitation pulse from the excitation laser arrives. Thus, stable generation of target droplets that travel from the target droplet generator to the zone of excitation at a uniform (or predictable) speed contributes to efficiency and stability of the LPP EUV radiation source.

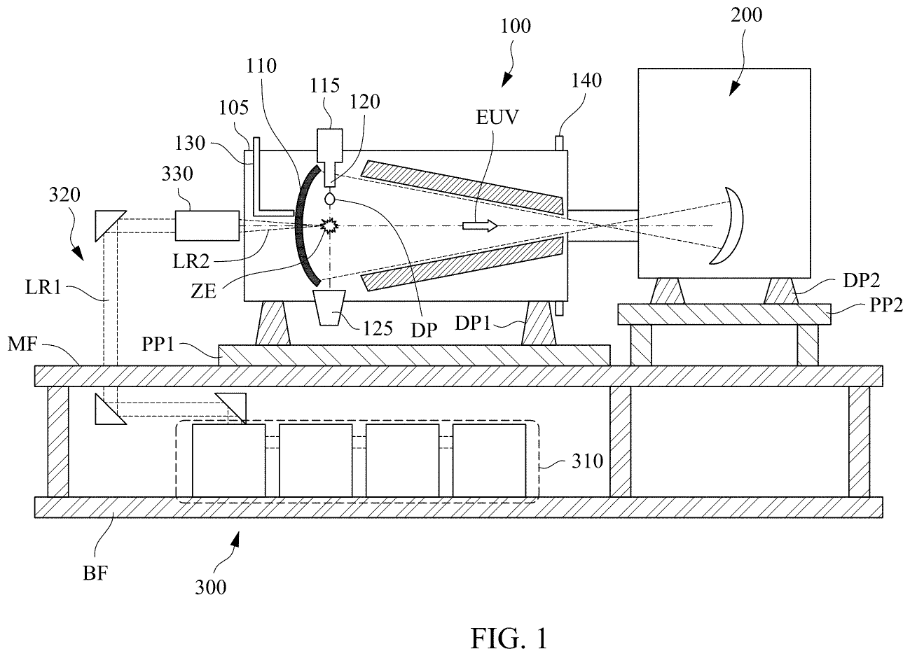

FIG. 1 is a schematic view of an EUV lithography tool with a laser production plasma (LPP) based EUV radiation source, constructed in accordance with some embodiments of the present disclosure. The EUV lithography system includes an EUV radiation source 100 to generate EUV radiation, an exposure device 200, such as a scanner, and an excitation laser source 300. As shown in FIG. 1, in some embodiments, the EUV radiation source 100 and the exposure device 200 are installed on a main floor MF of a clean room, while the excitation laser source 300 is installed in a base floor BF located under the main floor. Each of the EUV radiation source 100 and the exposure device 200 are placed over pedestal plates PP1 and PP2 via dampers DP1 and DP2, respectively. The EUV radiation source 100 and the exposure device 200 are coupled to each other by a coupling mechanism, which may include a focusing unit.

The EUV lithography tool is designed to expose a resist layer by EUV light (also interchangeably referred to herein as EUV radiation). The resist layer is a material sensitive to the EUV light. The EUV lithography system employs the EUV radiation source 100 to generate EUV light, such as EUV light having a wavelength ranging between about 1 nm and about 100 nm. In one particular example, the EUV radiation source 100 generates an EUV light with a wavelength centered at about 13.5 nm. In the present embodiment, the EUV radiation source 100 utilizes a mechanism of laser-produced plasma (LPP) to generate the EUV radiation.

The exposure device 200 includes various reflective optic components, such as convex/concave/flat mirrors, a mask holding mechanism including a mask stage, and wafer holding mechanism. The EUV radiation EUV generated by the EUV radiation source 100 is guided by the reflective optical components onto a mask secured on the mask stage. In some embodiments, the mask stage includes an electrostatic chuck (e-chuck) to secure the mask.

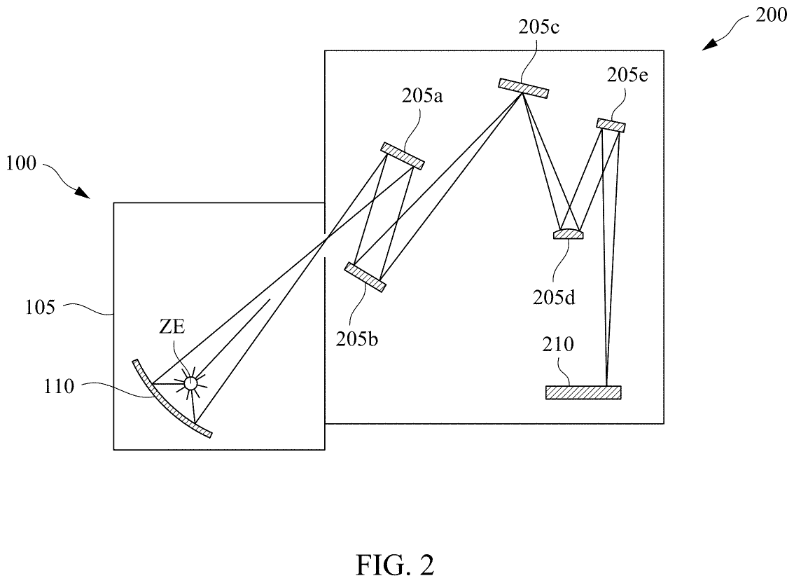

FIG. 2 is a simplified schematic diagram of a detail of an extreme ultraviolet lithography tool according to an embodiment of the disclosure showing the exposure of a photoresist-coated substrate 210 with a patterned beam of EUV light. The exposure device 200 is an integrated circuit lithography tool such as a stepper, scanner, step and scan system, direct write system, device using a contact and/or proximity mask, etc., provided with one or more optics 205a, 205b, for example, to illuminate a patterning optic 205c, such as a mask, with a beam of EUV light, to produce a patterned beam, and one or more reduction projection optics 205d, 205e, for projecting the patterned beam onto the substrate 210. A mechanical assembly (not shown) may be provided for generating a controlled relative movement between the substrate 210 and patterning optic 205c. As further shown in FIG. 2, the EUVL tool includes an EUV light source 100 including an EUV light radiator ZE emitting EUV light in a chamber 105 that is reflected by a collector 110 along a path into the exposure device 200 to irradiate the substrate 210.

As used herein, the term “optic” is meant to be broadly construed to include, and not necessarily be limited to, one or more components which reflect and/or transmit and/or operate on incident light, and includes, but is not limited to, one or more lenses, windows, filters, wedges, prisms, grisms, gratings, transmission fibers, etalons, diffusers, homogenizers, detectors and other instrument components, apertures, axicons and mirrors including multi-layer mirrors, near-normal incidence mirrors, grazing incidence mirrors, specular reflectors, diffuse reflectors and combinations thereof. Moreover, unless otherwise specified, neither the term “optic”, as used herein, are meant to be limited to components which operate solely or to advantage within one or more specific wavelength range(s) such as at the EUV output light wavelength, the irradiation laser wavelength, a wavelength suitable for metrology or any other specific wavelength.

Because gas molecules absorb EUV light, the lithography system for the EUV lithography patterning is maintained in a vacuum or a-low pressure environment to avoid EUV intensity loss.

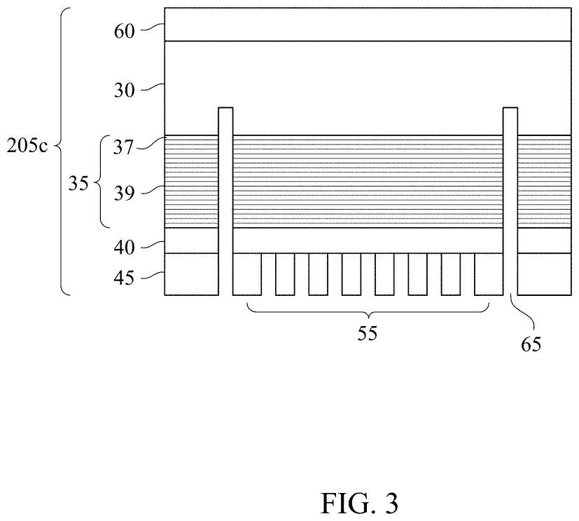

In the present disclosure, the terms mask, photomask, and reticle are used interchangeably. In the present embodiment, the patterning optic 205c shown in FIG. 3 is a reflective mask. In an embodiment, the reflective reticle 205c includes a substrate 30 with a suitable material, such as a low thermal expansion material or fused quartz, as shown in FIG. 3. In various examples, the material includes TiO₂ doped SiO₂, or other suitable materials with low thermal expansion. The reflective reticle 205c includes multiple reflective layers 35 deposited on the substrate. The multiple reflective layers 35 includes a plurality of film pairs, such as molybdenum-silicon (Mo/Si) film pairs (e.g., a layer of molybdenum 39 above or below a layer of silicon 37 in each film pair). Alternatively, the multiple reflective layers 35 may include molybdenum-beryllium (Mo/Be) film pairs, or other suitable materials that are configured to highly reflect the EUV light. The mask 205c may further include a capping layer 40, such as a layer made of ruthenium (Ru), disposed on the multiple reflective layers for protection. The mask further includes an absorption layer (or absorber) 45 deposited over the multiple reflective layers 35. The absorption layer 45 is patterned to define a layer of an integrated circuit (IC). Because the absorber 45 has a finite reflectivity, although the reflectivity of the absorber is much less than the reflectivity of the multiple reflective layers 35, the reflectivity of the absorber 45 coupled with the height of the absorber 45 above the multiple reflective layers 35 may create an undesirable phase shift of the EUV radiation reflected off the mask 205c. This undesirable phase shift of the EUV radiation is also called the mask 3D effect.

The reflective mask 205c includes a conductive backside coating 60 in some embodiments. In some embodiments, the reflective mask 205c includes a border 65 etched down to the substrate 30 surrounding the pattern 55, also known as a black border 65, to define a circuit area to be imaged and a peripheral area not to be imaged. The black border reduces light leakage in some embodiments.

In various embodiments of the present disclosure, the photoresist-coated substrate 210 is a semiconductor wafer, such as a silicon wafer or other type of wafer to be patterned.

The EUVL tool further include other modules or is integrated with (or coupled with) other modules in some embodiments.

As shown in FIG. 1, the EUV radiation source 100 includes a target droplet generator 115 and a LPP collector 110, enclosed by a chamber 105. In some embodiments, the target droplet generator 115 includes a reservoir to hold a source material and a nozzle 120 through which target droplets DP of the source material are supplied into the chamber 105.

In some embodiments, the target droplets DP are droplets of tin (Sn), lithium (Li), or an alloy of Sn and Li. In some embodiments, the target droplets DP each have a diameter in a range from about 10 microns (μm) to about 100 μm. For example, in an embodiment, the target droplets DP are tin droplets, having a diameter of about 10 μm to about 100 μm. In other embodiments, the target droplets DP are tin droplets having a diameter of about 25 μm to about 50 μm. In some embodiments, the target droplets DP are supplied through the nozzle 120 at a rate in a range from about 50 droplets per second (i.e., an ejection-frequency of about 50 Hz) to about 50,000 droplets per second (i.e., an ejection-frequency of about 50 kHz). In some embodiments, the target droplets DP are supplied at an ejection-frequency of about 100 Hz to a about 25 kHz. In other embodiments, the target droplets DP are supplied at an ejection frequency of about 500 Hz to about 10 kHz. The target droplets DP are ejected through the nozzle 127 and into a zone of excitation ZE at a speed in a range of about 10 meters per second (m/s) to about 100 m/s in some embodiments. In some embodiments, the target droplets DP have a speed of about 10 m/s to about 75 m/s. In other embodiments, the target droplets have a speed of about 25 m/s to about 50 m/s.

Referring back to FIG. 1, an excitation laser LR2 generated by the excitation laser source 300 is a pulse laser. The laser pulses LR2 are generated by the excitation laser source 300. The excitation laser source 300 may include a laser generator 310, laser guide optics 320 and a focusing apparatus 330. In some embodiments, the laser source 310 includes a carbon dioxide (CO₂) or a neodymium-doped yttrium aluminum garnet (Nd:YAG) laser source with a wavelength in the infrared region of the electromagnetic spectrum. For example, the laser source 310 has a wavelength of 9.4 μm or 10.6 μm, in an embodiment. The laser light LR1 generated by the laser generator 300 is guided by the laser guide optics 320 and focused into the excitation laser LR2 by the focusing apparatus 330, and then introduced into the EUV radiation source 100.

In some embodiments, the excitation laser LR2 includes a pre-heat laser and a main laser. In such embodiments, the pre-heat laser pulse (interchangeably referred to herein as the “pre-pulse) is used to heat (or pre-heat) a given target droplet to create a low-density target plume with multiple smaller droplets, which is subsequently heated (or reheated) by a pulse from the main laser, generating increased emission of EUV light.

In various embodiments, the pre-heat laser pulses have a spot size about 100 μm or less, and the main laser pulses have a spot size in a range of about 150 μm to about 300 μm. In some embodiments, the pre-heat laser and the main laser pulses have a pulse-duration in the range from about 10 ns to about 50 ns, and a pulse-frequency in the range from about 1 kHz to about 100 kHz. In various embodiments, the pre-heat laser and the main laser have an average power in the range from about 1 kilowatt (kW) to about 50 kW. The pulse-frequency of the excitation laser LR2 is matched with the ejection-frequency of the target droplets DP in an embodiment.

The laser light LR2 is directed through windows (or lenses) into the zone of excitation ZE. The windows adopt a suitable material substantially transparent to the laser beams. The generation of the pulse lasers is synchronized with the ejection of the target droplets DP through the nozzle 120. As the target droplets move through the excitation zone, the pre-pulses heat the target droplets and transform them into low-density target plumes. A delay between the pre-pulse and the main pulse is controlled to allow the target plume to form and to expand to an optimal size and geometry. In various embodiments, the pre-pulse and the main pulse have the same pulse-duration and peak power. When the main pulse heats the target plume, a high-temperature plasma is generated. The plasma emits EUV radiation EUV, which is collected by the collector mirror 110. The collector 110 further reflects and focuses the EUV radiation for the lithography exposing processes performed through the exposure device 200. The droplet catcher is used for catching excessive target droplets. For example, some target droplets may be purposely missed by the laser pulses.

Referring back to FIG. 1, the collector 110 is designed with a proper coating material and shape to function as a mirror for EUV collection, reflection, and focusing. In some embodiments, the collector 110 is designed to have an ellipsoidal geometry. In some embodiments, the coating material of the collector 100 is similar to the reflective multilayer of the EUV mask. In some examples, the coating material of the collector 110 includes an alternating stack of first and second reflective layers (such as a plurality of Mo/Si film pairs) and may further include a capping layer (such as Ru) coated on the ML to substantially reflect the EUV light. In some embodiments, the collector 110 may further include a grating structure designed to effectively scatter the laser beam directed onto the collector 110. For example, a silicon nitride layer is coated on the collector 110 and is patterned to have a grating pattern.

In such an EUV radiation source, the plasma caused by the laser application creates physical debris, such as ions, gases, and atoms of the droplet, as well as the desired EUV radiation. It is necessary to prevent the accumulation of material on the collector 110 and also to prevent physical debris exiting the chamber 105 and entering the exposure device 200.

As shown in FIG. 1, in the present embodiment, a buffer gas is supplied from a first buffer gas supply 130 through the aperture in collector 110 by which the pulse laser is delivered to the tin droplets. In some embodiments, the buffer gas is H₂, He, Ar, N₂, or another inert gas. In certain embodiments, H₂ used as H radicals generated by ionization of the buffer gas can be used for cleaning purposes. The buffer gas can also be provided through one or more second buffer gas supplies 135 toward the collector 110 and/or around the edges of the collector 110. Further, the chamber 105 includes one or more gas outlets 140 so that the buffer gas is exhausted outside the chamber 105.

Hydrogen gas has low absorption to the EUV radiation. Hydrogen gas reaching the coating surface of the collector 110 reacts chemically with a metal of the droplet forming a hydride, e.g., metal hydride. When tin (Sn) is used as the droplet, stannane (SnH₄), which is a gaseous byproduct of the EUV generation process, is formed. The gaseous SnH₄ is then pumped out through the outlet 140.

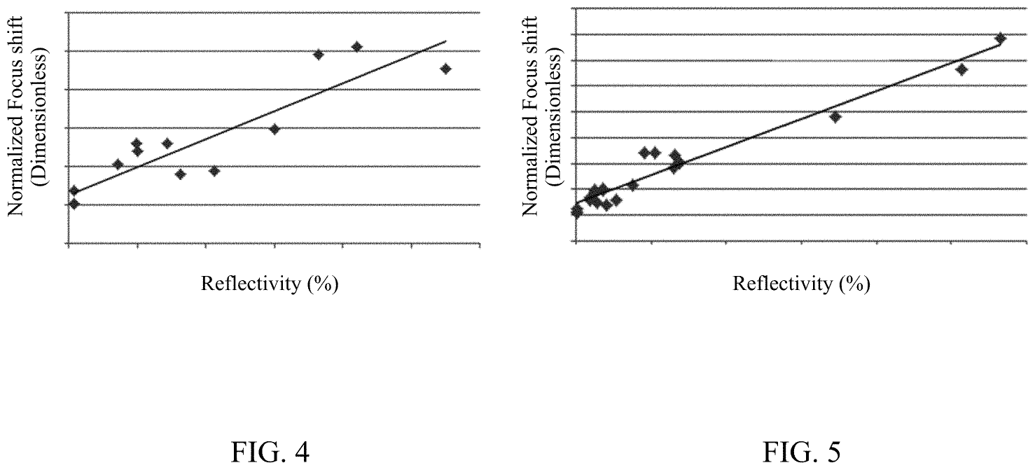

FIG. 4 is a graph showing a simulation of the absorber reflectivity versus the normalized horizontal best focus shift according to embodiments of the disclosure. FIG. 5 is a graph showing a simulation of the absorber reflectivity versus the normalized vertical best focus shift according to embodiments of the disclosure. R² in FIGS. 4 and 5 is the coefficient of determination, which is a measurement of the proportion of the variance in the dependent variable that is predictable from the independent variable, and provides a measure of how well observed outcomes are replicated by a model, based on the proportion of total variation of outcomes explained by the model. R² in FIG. 4 is 0.80±0.05 and R² in FIG. 5 is 0.95±0.05. The normalized best focus shift is defined as the best focus shift divided by the absorber thickness. The through-pitch normalized best focus shift is strongly correlated to the absorber reflectivity, i.e., smaller reflectivity leads to smaller normalized best focus shift. It is desirable to have an absorber thickness as small as possible while maintaining the reflectivity as low as possible to reduce the mask 3D effect. If the absorber is too thin, however, incident radiation will not be sufficiently absorbed by the absorber. The difference in the reflectivities in the horizontal and vertical orientations is because an EUV lithography system is a reflective, non-telecentric system. The EUV exposure radiation comes from a 6 degree angle of incidence, rather than a normal incidence. The oblique angle of incidence of the EUV radiation breaks the symmetry between the horizontally and vertically oriented patterns, thereby leading to differences in the exposure parameters of the horizontally and vertically oriented patterns.

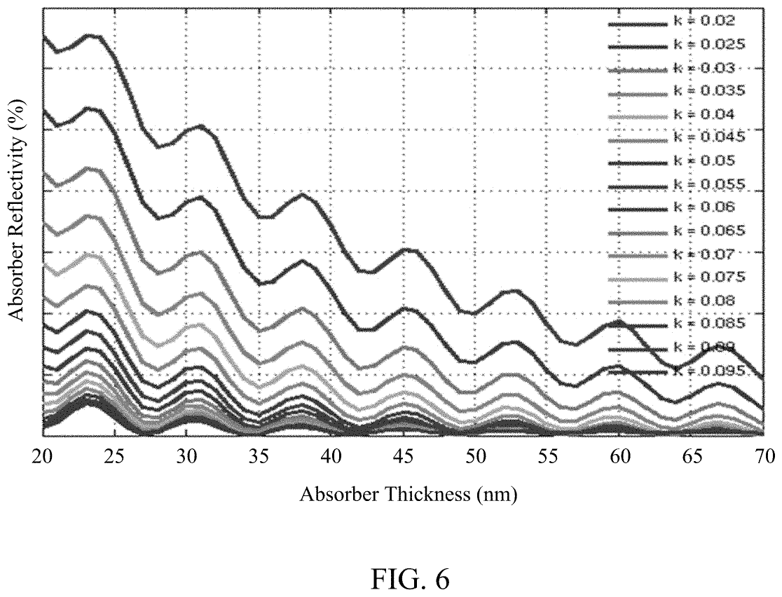

The lowest reflectivity of the absorber occurs at local minima of Fabry-Perot interference within the absorber. FIG. 6 is a graph of a simulation showing the absorber thickness versus absorber reflectivity at different extinction coefficients (k) according to embodiments of the disclosure. As shown in FIG. 6, it has been found that reflectivity minima are at absorber thicknesses of about 27 nm, about 30.5 nm, about 38.5 nm, about 48 nm, about 56 nm, and about 63 nm. However, the simulation illustrated in FIG. 6, was carried out without a capping layer. Factoring in a 3.5 nm ruthenium capping layer, the reflectivity minima layer thicknesses of the absorber are about 23.5 nm, about 30.5 nm, about 38.5 nm, about 52.5 nm, and about 59.5 nm, respectively. The extinction coefficient characterizes how easily a volume of material can be penetrated by a beam of light. As shown in FIG. 6, the higher the extinction coefficient, the lower the reflectivity. Therefore, it is desirable to use absorber materials with a high extinction coefficient.

The reflectivities at absorber layer thicknesses of about 30.5 nm and about 38.5 nm are lower than the absorber layer thickness reflectivity at about 23.5 nm. For example, the reflectivity at 23.5 nm is about 0.06, while the reflectivity at 30.5 nm is about 0.04, and the reflectivity at 38.5 nm is about 0.02. At greater thicknesses, the absorber layers may have mask 3D effect issues. In some embodiments, thinner absorber layers are desirable to reduce the mask 3D effect. In some embodiments, the thickness of the absorber 45 ranges from about 19.5 nm to about 43.5 nm. In some embodiments, the thickness of the absorber 45 ranges from about 21.5 to about 25.5 nm, from about 28.5 nm to about 32.5 nm, or from about 36.5 nm to about 40.5 nm. In some embodiments, absorber thicknesses outside of these ranges provide reduced photoresist pattern resolution.

According to embodiments of the present disclosure, the index of refraction, extinction coefficient, and the thickness of the absorber 45 are optimized to provide improved photolithographic performance. In some embodiments, the absorber 45 has an index of refraction ranging from about 0.87 to about 1.02. In some embodiments, the absorber 45 has an index of refraction ranging from about 0.90 to about 1.00. In some embodiments, the absorber 45 has an index of refraction of about 0.95. In some embodiments, the absorber 45 has an extinction coefficient ranging from about 0.065 to about 0.085. In some embodiments, the absorber 45 has an extinction coefficient ranging from about 0.070 to about 0.080. In some embodiments, extinction coefficients and indices of refraction outside of the above ranges provide reduced photoresist pattern resolution. In some embodiments, the absorber 45 has an extinction coefficient of about 0.075. In some embodiments, the absorber 45 has a thickness ranging from about 33.5 nm to about 43.5 nm. In some embodiments, the absorber 45 has a thickness ranging from about 35.5 nm to about 39.5 nm. In some embodiments, the absorber 45 has a thickness of about 38.5 nm.

In other embodiments, the absorber 45 has a thickness ranging from about 25.5 nm to about 35.5 nm. In some embodiments, the absorber 45 has a thickness ranging from about 27.5 nm to about 31.5 nm. In some embodiments, the absorber 45 has a thickness of about 30.5 nm. In other embodiments, the absorber 45 has an index of refraction ranging from about 0.87 to about 1.02. In some embodiments, the absorber 45 has an index of refraction ranging from about 0.90 to about 1.00. In some embodiments, the absorber 45 has an index of refraction of about 0.95. In some embodiments, the absorber 45 has an extinction coefficient ranging from about 0.085 to about 0.105. In some embodiments, the absorber 45 has an extinction coefficient ranging from about 0.090 to about 0.100. In some embodiments, the absorber 45 has an extinction coefficient of about 0.095. In some embodiments, extinction coefficients and indices of refraction outside of the above ranges provide reduced photoresist pattern resolution.

In some embodiments, the absorber 45 is made of material selected from the group consisting of Sn, Ni, Te, Co, In, Sb, and alloys of Sn, Ni, Te, Co, In, and Sb. In some embodiments, the absorber is made of a material selected from the group consisting of Sn, Ni, Te, and alloys thereof.

In an embodiment of the present disclosure, an absorption layer having a thickness of 38.5 nm provides a best focus shift improvement of 51.8% in a horizontal orientation and 39.8% in a vertical orientation; a critical depth of focus (cDOF) improvement of 11.2% in the horizontal orientation and 36.2% in the vertical orientation; an image log slope improvement of 1.2% in a horizontal orientation; and a horizontal-vertical bias (H-V Bias) improvement of 65.5% over an example having a TaBN/TaBO absorption layer, as determined by a simulation.

In an embodiment of the present disclosure, a simulation determined that an absorption layer having a thickness of 30.5 nm provides a best focus shift improvement of 64.1% in a horizontal orientation and 52.9% in a vertical orientation; a critical depth of focus (cDOF) improvement of 13.1% in the horizontal orientation and 29.4% in the vertical orientation; an image log slope improvement of 3.5% in a horizontal orientation and 1.1% in a vertical orientation; and a horizontal-vertical bias (H-V Bias) improvement of 77.9% over a TaBN/TaBO absorption layer.

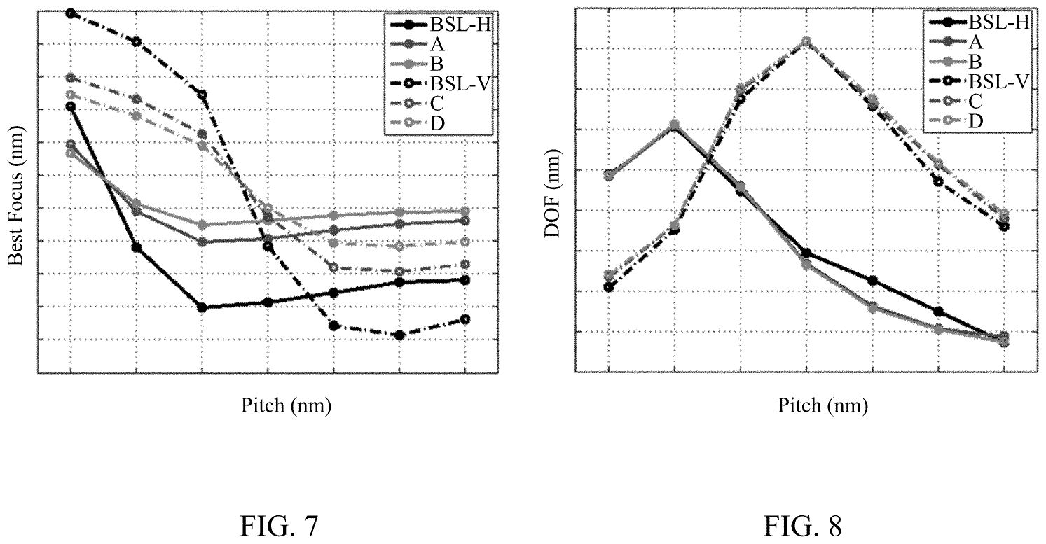

FIGS. 7-10 are graphs showing simulations of various exposure parameters across a range of pattern pitches. The various curves represent different thicknesses of absorber layers according to the present disclosure. In the simulations, the numerical aperture (NA) is 0.33 and a dipole radiation source is used. In FIGS. 7-10, BSL-H are horizontally-oriented patterns, BSL-V are vertically-oriented patterns. The BSL-H and BSL-V patterns are initial reference patterns. Patterns A and C are horizontally-oriented and vertically-oriented patterns, respectively, having an absorber thickness in a range of about 36.5 nm to about 40.5 nm. Patterns B and D are horizontally-oriented and vertically-oriented patterns, respectively, having an absorber thickness in a range of about 28.5 nm to about 32.5 nm.

FIG. 7 is a graph showing a simulation of the pattern pitch versus the best focus for TaBN/TaBO initial reference horizontal and vertical absorber examples (BSL) and Examples A, B, C, and D according to the present disclosure. As shown in FIG. 7, Examples A, B, C, and D show a clear improvement over the BSL absorber examples. There is less variation in the best focus of Examples A, B, C, and D over the range of pattern pitch, in contrast to the BSL examples. Examples A, B, C, and D have a flatter best focus across the range of pitches.

FIG. 8 is a graph of a simulation showing the pattern pitch versus the individual depth of focus (iDOF) for horizontal and vertical TaBN/TaBO absorber initial reference examples (BSL) and Examples A, B, C, and D according to the present disclosure. As shown in FIG. 8, the Examples A, B, C, and D have a comparable individual depth of focus as the BSL examples.

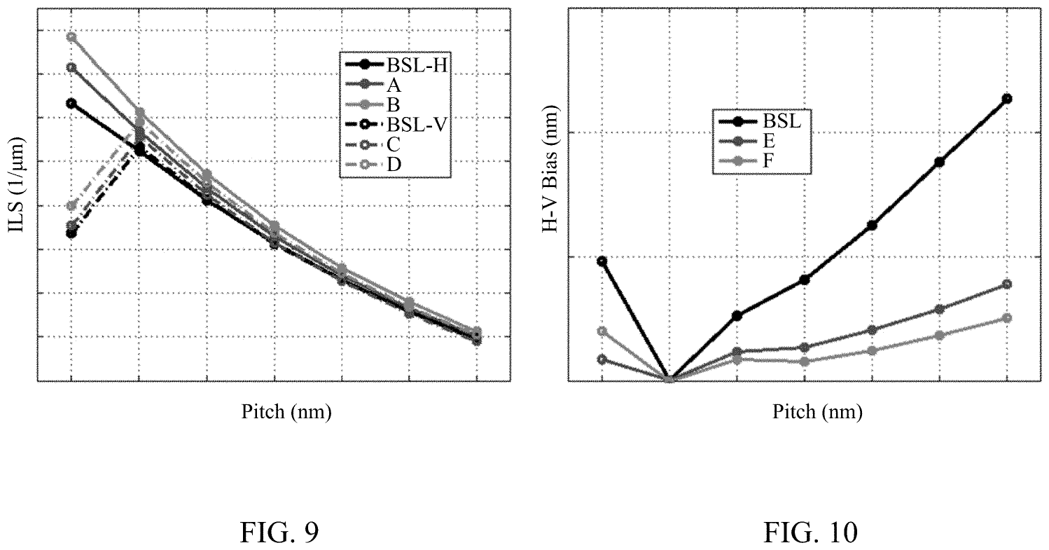

FIG. 9 is a simulation of a graph showing the pattern pitch versus the image log-slope (ILS) for horizontal and vertical TaBN/TaBO absorber initial reference examples (BSL) and Examples A, B, C, and D according to the present disclosure. As shown in FIG. 9, Examples A, B, C, and D are improved at the higher pitch densities (lower pitch value) relative to the BSL examples. The ILS measure the steepness of a pattern at its edge. The slope of image intensity as a function of position (dI/dx) measures the steepness of the image in the transition from bright to dark. The image log-slope is the slope of the image intensity divided by the intensity: image log-slope=(1/I)(dI/dx)=d1n(I)/dx.

FIG. 10 is a graph of a simulation showing the pattern pitch versus the horizontal-vertical bias (H-V Bias) for the TaBN/TaBO absorber initial reference example (BSL) and Example E and F of absorbers according to the present disclosure. Patterns E have an absorber thickness in a range of about 36.5 nm to about 40.5 nm. Patterns F have an absorber thickness in a range of about 28.5 nm to about 32.5 nm. As shown in FIG. 10, the H-V Bias of the Examples E and F are clearly improved over the BSL examples.

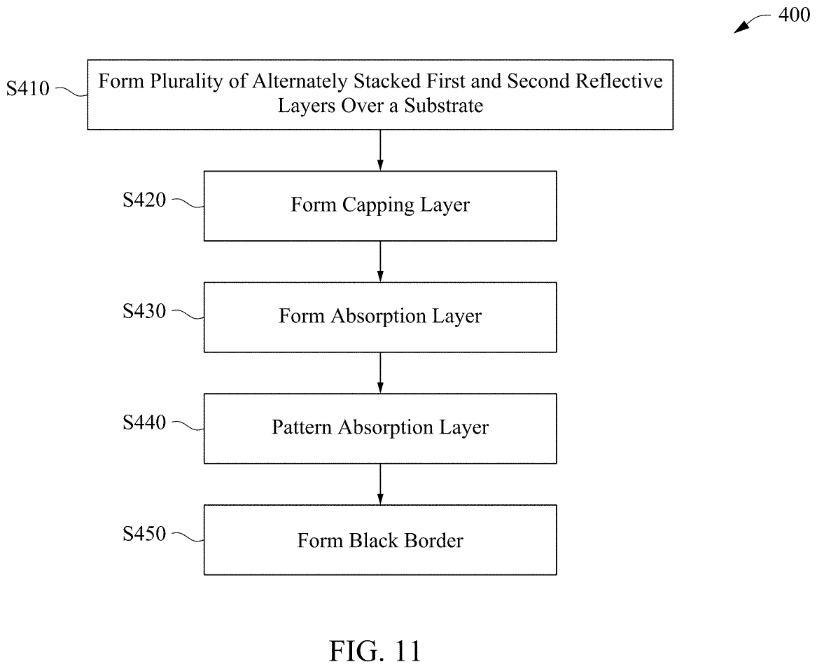

FIG. 11 is a flowchart illustrating a method 400 of manufacturing an extreme ultraviolet mask according to an embodiment of the disclosure. In some embodiments, the mask is a reflective mask used to form selectively expose photoresist coated substrates to extreme ultraviolet radiation. In operation S410, a plurality of alternately stacked first reflective layers 37 and second reflective layers 39 are formed over a substrate 30 (see FIG. 3). The substrate 30 is made of a low thermal expansion material, such as titanium dioxide doped silicon dioxide in some embodiments. In some embodiments, the first reflective layer 37 is silicon and the second reflective layer 39 is molybdenum.

In some embodiments, from about 30 alternating layers each of silicon and molybdenum to about 60 alternating layers each of silicon and molybdenum are formed. In certain embodiments, from about 40 to about 50 alternating layers each of silicon and molybdenum are formed. In some embodiments, the silicon and molybdenum layers are formed by chemical vapor deposition (CVD), plasma-enhanced CVD (PECVD), atomic layer deposition (ALD), physical vapor deposition (PVD) (sputtering), or any other suitable film forming method. Each layer of silicon and molybdenum is about 2 nm to about 10 nm thick. In some embodiments, the layers of silicon and molybdenum are about the same thickness. In other embodiments, the layers of silicon and molybdenum are different thicknesses. In some embodiments, the thickness of each layer of silicon and molybdenum is about 3 nm to about 4 nm.

In operation S420, a capping layer 40 is subsequently formed over the Mo/Si multilayer 35 in some embodiments. In some embodiments, the capping layer 40 is made of ruthenium having a thickness of from about 2 nm to about 10 nm. In certain embodiments, the thickness of the capping layer 40 is from about 2 nm to about 4 nm. In certain embodiments, the thickness of the capping layer 40 is about 3.5 nm. In some embodiments, the capping layer 40 is formed by chemical vapor deposition, plasma-enhanced chemical vapor deposition, atomic layer deposition, physical vapor deposition, or any other suitable film forming method.

Then, an absorber layer is formed over the capping layer 40 in operation S430 in some embodiments. In some embodiments, the absorber layer is made of material selected from the group consisting of Sn, Ni, Te, Co, In, Sb, and alloys of Sn, Ni, Te, Co, In, and Sb. In some embodiments, the absorber is made of a material selected from the group consisting of Sn, Ni, Te, and alloys thereof. In some embodiments, the thickness of the absorber layer ranges from about 19.5 nm to about 43.5 nm. In some embodiments, the thickness of the absorber layer ranges from about 25.5 nm to about 35.5 nm. In other embodiments, the thickness of the absorber layer ranges from about 33.5 nm to about 43.5 nm.

In some embodiments, the absorber layer is formed by chemical vapor deposition, plasma-enhanced chemical vapor deposition, atomic layer deposition, physical vapor deposition, or any other suitable film forming method.

The absorber layer is subsequently patterned to form the absorber 45 in operation S440 in some embodiments. The pattern formed in the absorber 45 corresponds to an integrated circuit pattern to be formed on a semiconductor substrate in some embodiments. In some embodiments, the pattern is formed by suitable photolithographic and etching operations. For example, a photoresist layer is formed over the absorber layer, and the photoresist layer is selectively exposed with actinic radiation. The actinic radiation includes ultraviolet and deep ultraviolet radiation, electron beam, and ion beam. The photoresist is a positive-tone resist or a negative-tone resist. The selectively exposed photoresist layer is subsequently developed using a suitable developer to form a pattern in the photoresist. The pattern in the photoresist is extended into the absorber layer using a suitable etching operation in some embodiments. The etching operation may be a wet etching operation or a dry etching operation. In some embodiments, the pattern in the absorber layer exposes the capping layer 40. In some embodiments, the pattern is extended into the capping layer 40. After forming the pattern in the absorber layer, the remaining photoresist is removed by a suitable photoresist stripping or plasma ashing operation, thereby forming the patterned absorber 45.

In some embodiments, a black border 65 is formed to define the circuit area to be imaged and the peripheral area not to be imaged in operation S450. The black border 65 is formed by suitable photolithographic and etching operations. In some embodiments, the black border pattern extends from the absorber 45 surface into the substrate 10.

In some embodiments, a conductive layer 60 is formed on a second main surface of the substrate 10 opposing the first main surface of the substrate 10 on which the Mo/Si multilayer 35 is formed. In some embodiments, the conductive layer 60 is made of chromium, chromium nitride, or TaB having a thickness of about 25 nm to about 150 nm. In some embodiments, the conductive layer 60 has a thickness of about 70 nm to about 100 nm. In some embodiments, the conductive layer 60 is formed by chemical vapor deposition, plasma-enhanced chemical vapor deposition, atomic layer deposition, physical vapor deposition, or any other suitable film forming method.

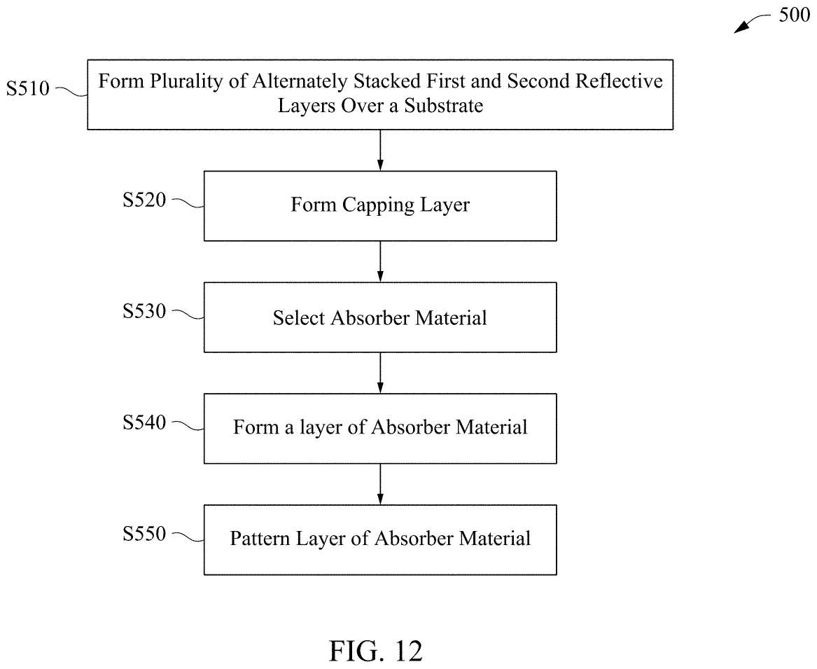

In other embodiments of the present disclosure, a method 500 of optimizing an absorption layer for an extreme ultraviolet mask is provided, as shown in the flowchart of FIG. 12. A plurality of alternately stacked first reflective layers 37 and second reflective layers 39 are formed over a substrate 30 (see FIG. 3). The substrate 30 is made of a low thermal expansion material, such as titanium dioxide doped silicon dioxide in some embodiments. In some embodiments, the first reflective layer 37 is silicon and the second reflective layer 39 is molybdenum.

In some embodiments, from about 30 alternating layers each of silicon and molybdenum to about 60 alternating layers each of silicon and molybdenum are formed. In certain embodiments, from about 40 to about 50 alternating layers each of silicon and molybdenum are formed. In some embodiments, the silicon and molybdenum layers are formed by chemical vapor deposition (CVD), plasma-enhanced CVD (PECVD), atomic layer deposition (ALD), physical vapor deposition (PVD) (sputtering), or any other suitable film forming method. Each layer of silicon and molybdenum is about 2 nm to about 10 nm thick. In some embodiments, the layers of silicon and molybdenum are about the same thickness. In other embodiments, the layers of silicon and molybdenum are different thicknesses. In some embodiments, the thickness of each layer of silicon and molybdenum is about 3 nm to about 4 nm.

In operation S520, a capping layer 40 is subsequently formed over the Mo/Si multilayer 35 in some embodiments. In some embodiments, the capping layer 40 is made of ruthenium having a thickness of from about 2 nm to about 10 nm. In certain embodiments, the thickness of the capping layer 40 is from about 2 nm to about 4 nm. In certain embodiments, the thickness of the capping layer 40 is about 3.5 nm. In some embodiments, the capping layer 40 is formed by chemical vapor deposition, plasma-enhanced chemical vapor deposition, atomic layer deposition, physical vapor deposition, or any other suitable film forming method.

Then, an absorber material is selected in operation S530. The absorber material has an index of refraction ranging from about 0.87 to about 1.02, an extinction coefficient ranging from about 0.065 to about 0.085, and a thickness ranging from about 33.5 nm to about 35.5 nm in some embodiments. In other embodiments, the absorber material has an index of refraction ranging from about 0.87 to about 1.02, an extinction coefficient ranging from about 0.085 to about 0.105, and a thickness ranging from about 25.5 nm to about 35.5 nm.

A layer of the absorber material is subsequently formed over the capping layer 40 and/or the plurality of alternately stacked first reflective layers and second reflective layers 35 in operation S540. In some embodiments, the layer of absorber material is made of material selected from the group consisting of Sn, Ni, Te, Co, In, Sb, and alloys of Sn, Ni, Te, Co, In, and Sb. In some embodiments, the absorber is made of a material selected from the group consisting of Sn, Ni, Te, and alloys thereof. In some embodiments, the layer of absorber material is formed by chemical vapor deposition, plasma-enhanced chemical vapor deposition, atomic layer deposition, physical vapor deposition, or any other suitable film forming method.

In some embodiments, the layer of absorber material is subsequently patterned in operation S550 in some embodiments. The pattern formed in the layer of absorber material corresponds to an integrated circuit pattern to be formed on a semiconductor substrate in some embodiments. In some embodiments, the pattern is formed by suitable photolithographic and etching operations.

In some embodiments, additional operations are performed on the extreme ultraviolet mask, including forming a backside conductive layer and a black border surrounding the image imaging area of the mask.

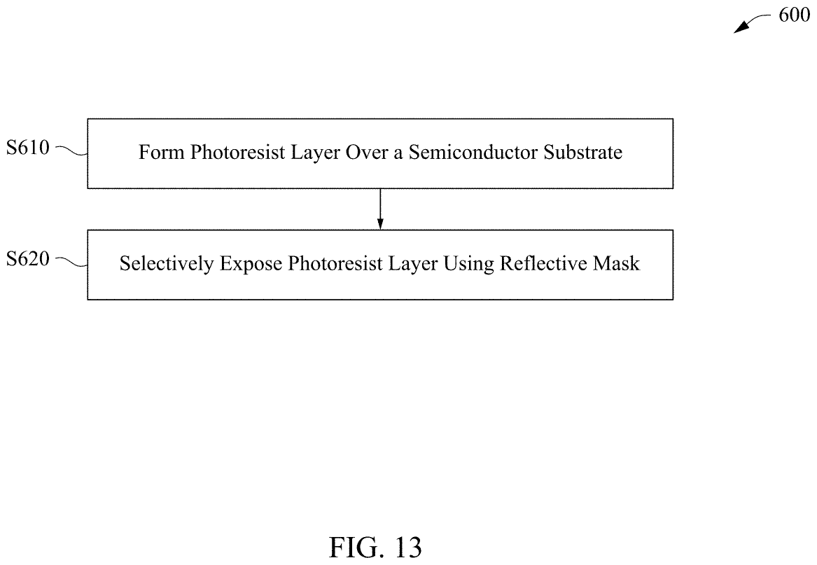

FIG. 13 is a flowchart illustrating a method 600 of manufacturing a semiconductor device according to an embodiment of the disclosure. In operation S610, a photoresist layer is formed over a semiconductor substrate. In some embodiments, the semiconductor substrate includes a single crystalline semiconductor layer on at least it surface portion. The substrate may include a single crystalline semiconductor material such as, but not limited to Si, Ge, SiGe, GaAs, InSb, GaP, GaSb, InAlAs, InGaAs, GaSbP, GaAsSb and InP. In certain embodiments, the substrate is made of crystalline Si.

In some embodiments, the photoresist layer includes a positive-tone or negative-tone photoresist. In some embodiments, the photoresist includes a photoactive compound, a polymer, and a solvent. In some embodiments, the photoactive compound is a photoacid generator and the polymer includes acid-labile groups.

In operation S620, the photoresist layer is selectively exposed by actinic radiation using a reflective mask. In some embodiments, the actinic radiation is extreme ultraviolet radiation. In some embodiments, the reflective mask includes an absorber having an index of refraction ranging from about 0.87 to about 1.02, an extinction coefficient ranging from about 0.065 to about 0.085, and a thickness ranging from about 33.5 nm to about 35.5 nm. In other embodiments, the absorber has an index of refraction ranging from about 0.87 to about 1.02, an extinction coefficient ranging from about 0.085 to about 0.105, and a thickness ranging from about 25.5 nm to about 35.5 nm. In some embodiments, the absorber is patterned with a pattern of an integrated circuit to be formed on the photoresist-coated substrate. In some embodiments, the absorber is disposed over a plurality of alternately stacked first and second reflective layers overlying a substrate.

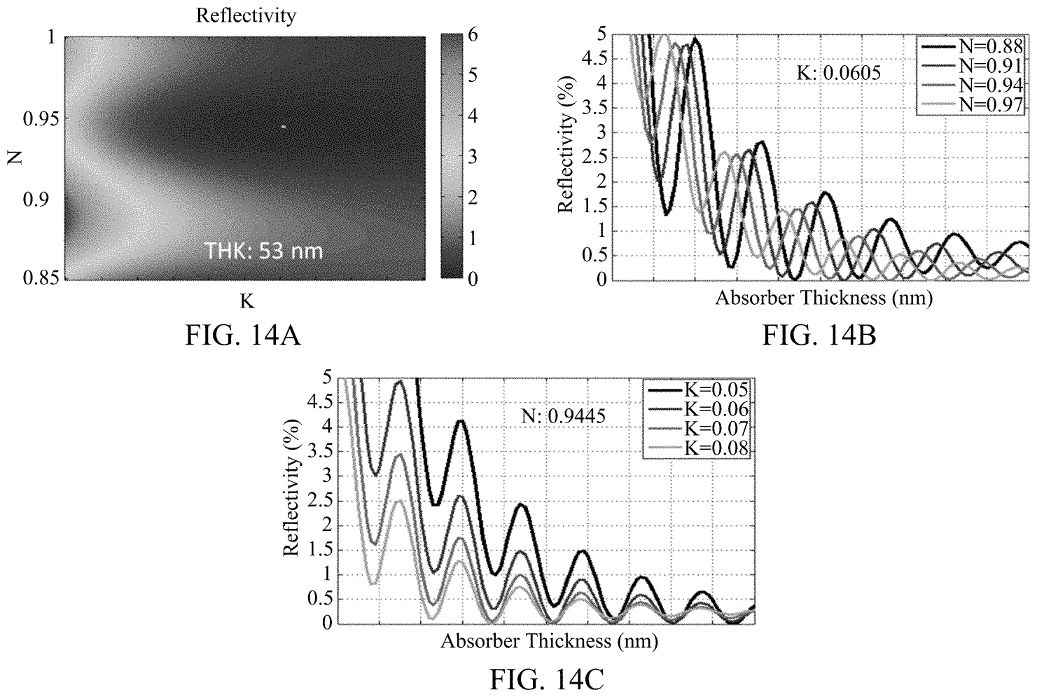

In some embodiments, as explained herein, the index of refraction N was set to 0.95, and the extinction coefficient K and absorber layer thickness T were optimized in a simulation. In other embodiments of the disclosure, N, K, and T are all optimized in a simulation. FIGS. 14A, 14B, and 14C illustrate the results of a simulation for optimizing the reflectivity of an EUV mask including an absorber layer disposed over a 3.5 nm thick ruthenium capping layer disposed over 40 pairs of 3.0 nm thick Mo layers and 4.0 nm thick Si layers according to an embodiment. The thickness of the absorber layer is varied from 20 nm to 70 nm, the index of refraction is varied from 0.85 to 1.0, and the extinction coefficient is varied from 0.03 to 0.08. FIG. 14A illustrates the reflectivity of a 53 nm thick absorber layer as the index of refraction N and the extinction coefficient are varied. FIG. 14B illustrates the variation in absorber layer thickness T versus reflectivity at various indices of refraction at an extinction coefficient K=0.605. FIG. 14C illustrates the variation in absorber layer thickness T versus reflectivity at various extinction coefficients at an index of refraction N=0.9445. It was found in this simulation that a minimum reflectivity of 2.00×10⁻⁵ is obtained at an absorber layer thickness T of about 53 nm, an index of refraction N in a range of about 0.944 to about 0.945, and extinction coefficient K in a range of about 0.060 to about 0.061.

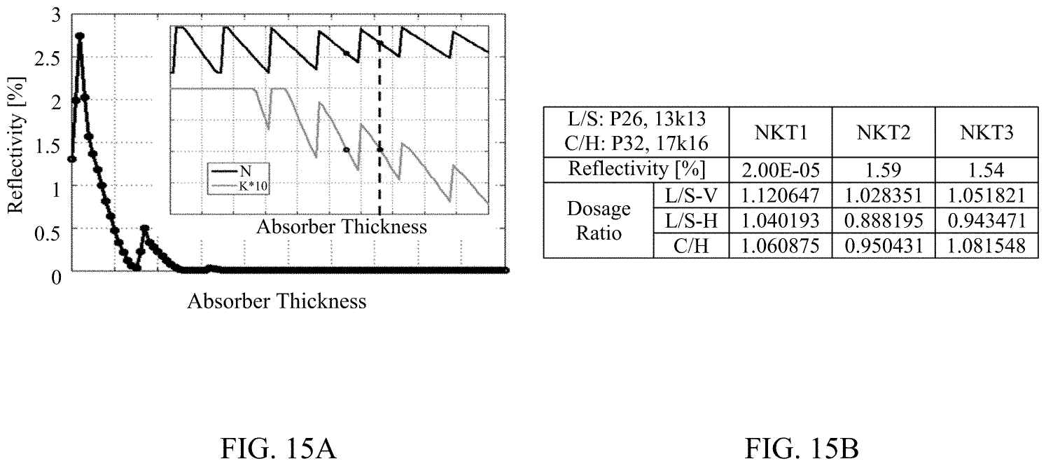

The minimum reflectivity at each absorber thickness through the NK range was determined in a simulation of the EUV mask discussed in reference to FIGS. 14A and 14B, as shown in FIG. 15A. The NK values corresponding to the minimum reflectivity are shown in the inset of FIG. 15A, and the global minimum reflectivity at about 53 nm absorber layer thickness T is shown by the dashed line. The results of this simulation for NKT2=(0.944 to 0.945, 0.060 to 0.061, 34.5 to 38.5) and NKT3=(0.900 to 0.902, 0.060 to 0.061, 30 to 34) compared to the global reflection minima range NKT1=(0.944 to 0.945, 0.060 to 0.061, 51 to 55) are shown in the table of FIG. 15B. L/S-V refers to a vertical line and space; L/S-H refers to a horizontal line and space; and C/H refers to a contact hole. L/S, P26, 13k13: refers to line/space having a pitch of 26 nm, the first 13 is the width at the mask (nm). The second 13 is the width at wafer (nm). C/H, P32, 17k16: refers to contact a hole pitch 32 (nm), the width at mask 17 nm, and width at wafer 16 nm. The global reflection minima is the minima through the entire curves where many local minima are observed.

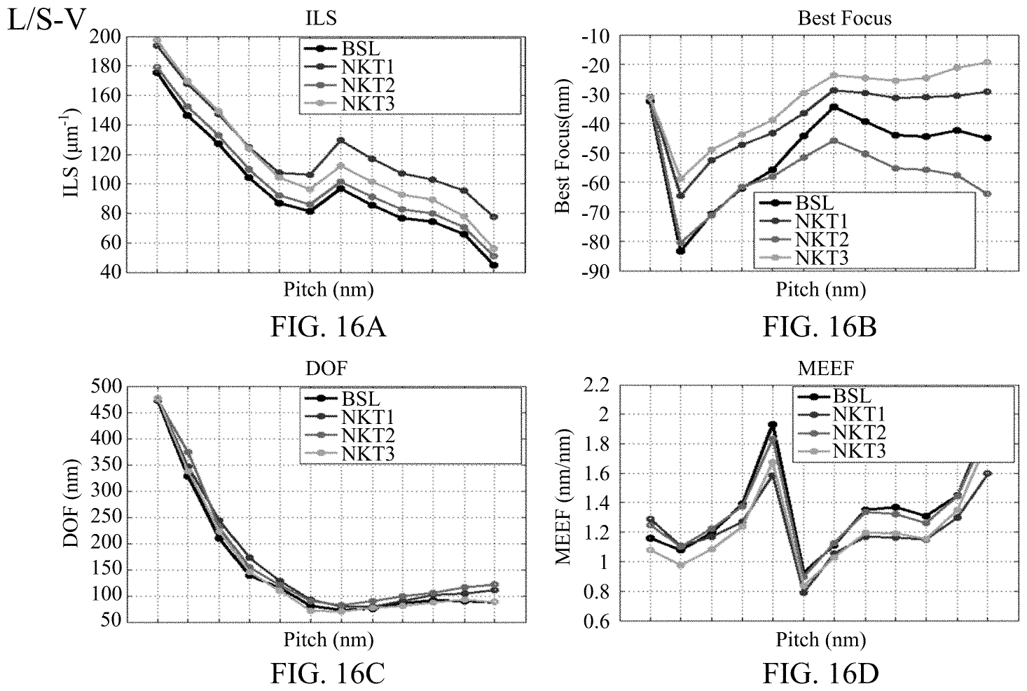

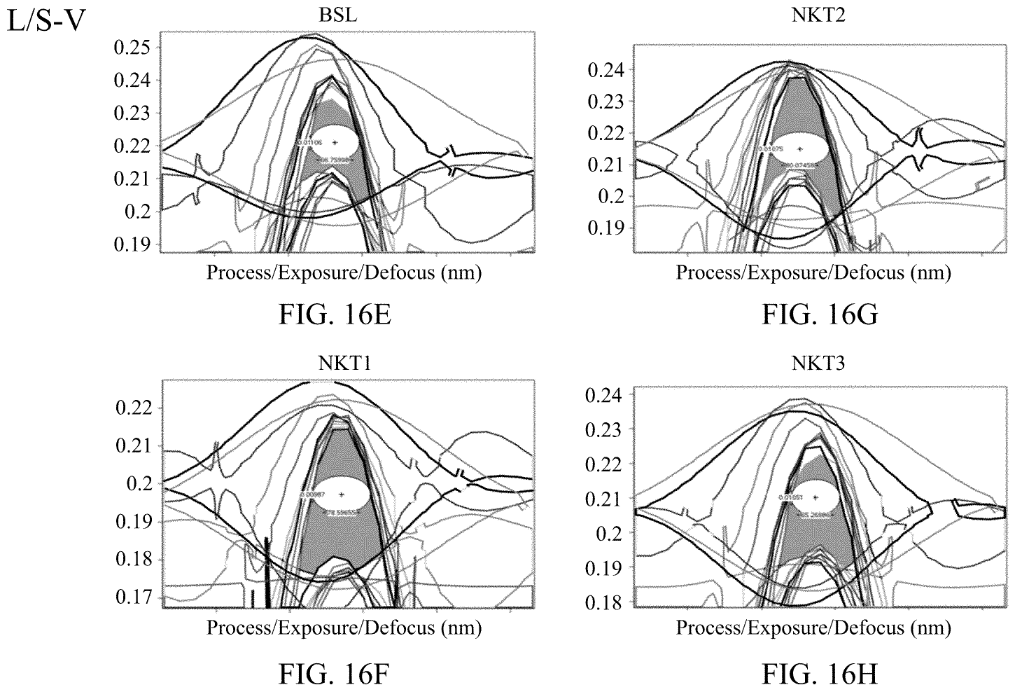

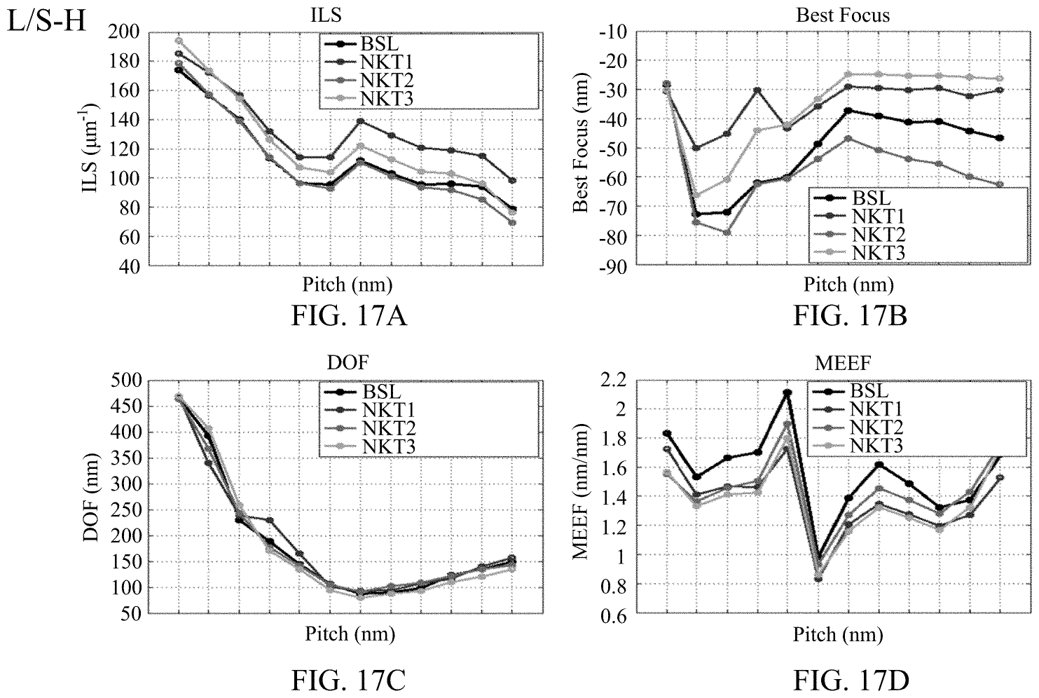

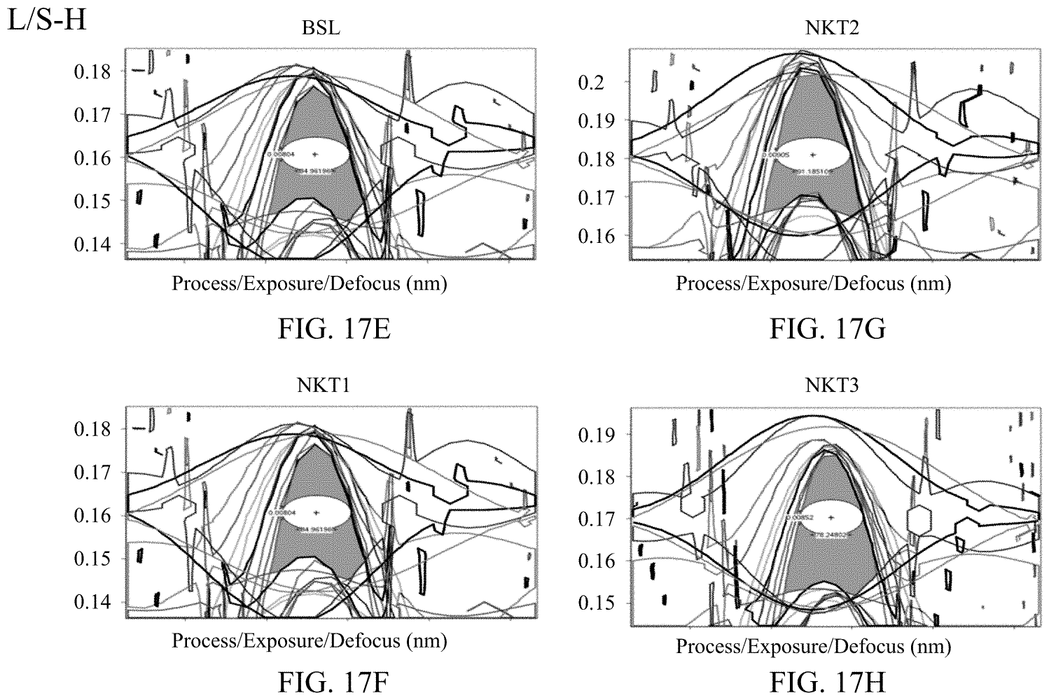

The simulated optimization results of an EUV mask for L/S-V for vertically oriented patterns and L/S-H for horizontally oriented patterns are shown in FIGS. 16A-16H and FIGS. 17A-17H, respectively. FIGS. 16A and 17A show the image log-slope. FIGS. 16B and 17B show the best focus shift. FIGS. 16C and 17C show the critical depth of focus. FIGS. 16D and 17D show the mask error enhancement factor. FIGS. 16E, 16F, 16G, and 16H show the exposure defocus v. bulk image threshold intensity for the initial reference EUV mask BSL and Examples NKT1, NKT2, and NKT3, where NKT1=(0.944 to 0.945, 0.060 to 0.061, 51 to 55), NKT2=(0.944 to 0.945, 0.060 to 0.061, 34.5 to 38.5), and NKT3=(0.900 to 0.902, 0.060 to 0.061, 30 to 34), respectively for L/S-V for vertically oriented patterns. FIGS. 17E, 17F, 17G, and 17H show the exposure defocus v. bulk image threshold intensity for the baseline EUV mask, where NKT1=(0.944 to 0.945, 0.060 to 0.061, 53), NKT2=(0.944 to 0.945, 0.060 to 0.061 to, 34.5 to 38.5), and NKT3=(0.900 to 0.902, 0.060 to 0.061, 30 to 34) respectively for L/S-V for horizontally oriented patterns.

In some embodiments, an extreme ultraviolet mask includes a capping layer disposed over multiple pairs of reflective layers, and a patterned absorber disposed over the capping layer. The absorber has an index of refraction ranging from about 0.895 to about 0.950 in some embodiments, and about 0.90 to about 0.945 in other embodiments. In some embodiments, the index of refraction is about 0.901. In some embodiments, the index of refraction is about 0.9445. In some embodiments, the absorber has an extinction coefficient ranging from about 0.0600 to about 0.0610, and an extinction coefficient ranging from about 0.0603 to about 0.0607 in other embodiments. In some embodiments, the absorber has an extinction coefficient of about 0.0605. In some embodiments, the absorber has a thickness ranging from about 30 nm to about 39 nm. In other embodiments, the absorber has a thickness ranging from about 50 nm to about 55 nm. In an embodiment, the absorber has a thickness ranging from about 31 nm to about 37 nm. In some embodiments, the absorber has a thickness of about 32 nm. In some embodiments, the absorber has a thickness of about 36.5 nm. In some embodiments, the absorber has a thickness of about 53 nm.

EUV masks and methods of manufacturing EUV masks according to the present disclosure provide reduced mask 3D effect by reducing the absorber thickness and reducing the reflectivity of the absorber. EUV masks and methods of manufacturing EUV masks according to the present disclosure provide improved EUV lithography performance including improved horizontal-vertical bias, improved best focus, and improved depth of focus.

An embodiment of the present disclosure is an extreme ultraviolet mask, including an absorber having an index of refraction ranging from 0.87 to 1.02, an extinction coefficient ranging from 0.065 to 0.085, and a thickness ranging from 33.5 nm to 43.5 nm. In an embodiment, the absorber has an index of refraction ranging from 0.90 to 1.00. In an embodiment, the absorber has an index of refraction of 0.95. In an embodiment, the absorber has an extinction coefficient ranging from 0.070 to 0.080. In an embodiment, the absorber has an extinction coefficient of 0.075. In an embodiment, the absorber has a thickness has a thickness ranging from 39 nm to 43 nm. In an embodiment, the absorber has a thickness of 38.5 nm. In an embodiment, the absorber is made of a material selected from the group consisting of Sn, Ni, Te, and alloys of Sn, Ni, and Te.

Another embodiment of the present disclosure is an extreme ultraviolet mask, including an absorber having an index of refraction ranging from 0.87 to 1.02, an extinction coefficient ranging from 0.085 to 0.105, and a thickness ranging from 25.5 nm to 35.5 nm. In an embodiment, the absorber has an index of refraction ranging from 0.90 to 1.00. In an embodiment, the absorber has an index of refraction of 0.95. In an embodiment, the absorber has an extinction coefficient ranging from 0.090 to about 0.100. In an embodiment, the absorber has an extinction coefficient of 0.095. In an embodiment, the absorber has a thickness has a thickness ranging from 27.5 nm to 31.5 nm. In an embodiment, the absorber has a thickness of 30.5 nm.

Another embodiment of the disclosure is an extreme ultraviolet mask, including an absorber having an index of refraction ranging from 0.895 to 0.950, an extinction coefficient ranging from 0.0600 to 0.0610, and a thickness ranging from 30 nm to 39 nm or 50 nm to 55 nm. In an embodiment, the thickness ranges from 30 to 34 nm. In an embodiment, the thickness ranges from 34.5 nm to 38.5 nm. In an embodiment, the thickness ranges from 51 to 55 nm. In an embodiment, the absorber has an index of refraction ranging from 0.944 to 0.945. In an embodiment, the absorber has an index of refraction ranging from 0.900 to 0.902. In an embodiment, the absorber has an index of refraction ranging from 0.90 to 0.945, and an extinction coefficient of 0.0605. In an embodiment, the absorber has an index of refraction of 0.9445, and a thickness of 36.5 nm. In an embodiment, the absorber has an index of refraction of 0.901, and a thickness of 32 nm. In an embodiment, the absorber has an index of refraction of 0.9445, and a thickness of 53 nm.

Another embodiment of the disclosure is a method of manufacturing an extreme ultraviolet mask, including forming a plurality of alternately stacked first reflective layers and second reflective layers over a substrate. An absorption layer is formed over the plurality of alternately stacked first and second reflective layers. The absorption layer has an index of refraction ranging from 0.87 to 1.02, an extinction coefficient ranging from 0.065 to 0.085, and a thickness ranging from 33.5 nm to 43.5 nm. In an embodiment, the method includes forming a capping layer between the plurality of alternately stacked first and second reflective layers and the absorption layer. In an embodiment, the capping layer is made of ruthenium. In an embodiment, the plurality of alternately stacked first and second reflective layers includes a plurality of pairs of molybdenum and silicon layers. In an embodiment, the absorber has an index of refraction ranging from 0.90 to 1.00. In an embodiment, the absorber has an index of refraction of 0.95. In an embodiment, the absorber has an extinction coefficient ranging from 0.070 to 0.080. In an embodiment, the absorber has an extinction coefficient of 0.075. In an embodiment, the absorber has a thickness ranging from 35.5 nm to 39.5 nm. In an embodiment, the absorber has a thickness of 38.5 nm. In an embodiment, the absorber is made of a material selected from the group consisting of Sn, Ni, Te, and alloys of Sn, Ni, and Te.

Another embodiment of the disclosure is a method of manufacturing an extreme ultraviolet mask, including forming plurality of alternately stacked first reflective layers and second reflective layers over a substrate. An absorption layer is formed over the plurality of alternately stacked first and second reflective layers. The absorber has an index of refraction ranging from 0.87 to 1.02, an extinction coefficient ranging from 0.085 to 0.105, and a thickness ranging from 25.5 nm to 35.5 nm. In an embodiment, the method includes forming a capping layer between the plurality of alternately stacked first and second reflective layers and the absorption layer. In an embodiment, the capping layer is made of ruthenium. In an embodiment, the plurality of alternately stacked first and second reflective layers includes a plurality of pairs of molybdenum and silicon layers. In an embodiment, the absorber has an index of refraction ranging from 0.90 to 1.00. In an embodiment, the absorber has an index of refraction of 0.95. In an embodiment, the absorber has an extinction coefficient ranging from 0.090 to about 0.100. In an embodiment, the absorber has an extinction coefficient of 0.095. In an embodiment, the absorber has a thickness has a thickness ranging from 27.5 nm to 31.5 nm. In an embodiment, the absorber has a thickness of 30.5 nm.

Another embodiment of the disclosure is a method of optimizing an absorption layer for an extreme ultraviolet mask, including forming a plurality of alternately stacked first reflective layers and second reflective layers over a substrate. An absorber material having an index of refraction ranging from 0.87 to 1.02, an extinction coefficient ranging from 0.065 to 0.085, and a thickness ranging from 33.5 nm to 43.5 nm is selected. A layer of the absorber material is formed over the plurality of alternately stacked first and second reflective layers.

Another embodiment of the disclosure is a method of optimizing an absorption layer for an extreme ultraviolet mask, including forming a plurality of alternately stacked first reflective layers and second reflective layers over a substrate. An absorber material having an index of refraction ranging from 0.87 to 1.02, an extinction coefficient ranging from 0.085 to 0.105, and a thickness ranging from 25.5 nm to 35.5 nm is selected, and a layer of the absorber material is formed over the plurality of alternately stacked first and second reflective layers.

Another embodiment of the disclosure is a method of manufacturing a semiconductor device, including forming a photoresist layer over a semiconductor substrate, and selectively exposing the photoresist layer to actinic radiation that is reflected off a reflective mask. The reflective mask includes: an absorber having an index of refraction ranging from 0.87 to 1.02, an extinction coefficient ranging from 0.065 to 0.085, and a thickness ranging from 33.5 nm to 43.5 nm.

Another embodiment of the disclosure is a method of manufacturing a semiconductor device, including forming a photoresist layer over a semiconductor substrate, and selectively exposing the photoresist layer to actinic radiation that is reflected off a reflective mask. The reflective mask includes: an absorber having an index of refraction ranging from 0.87 to 1.02, an extinction coefficient ranging from 0.085 to 0.105, and a thickness ranging from 25.5 nm to 35.5 nm.

Another embodiment of the disclosure is a method of manufacturing a semiconductor device, including forming a photoresist layer over a semiconductor substrate, and selectively exposing the photoresist layer to actinic radiation that is reflected off a reflective mask. The reflective mask includes: an absorber having an index of refraction ranging from 0.895 to 0.950, an extinction coefficient ranging from 0.0600 to 0.0610, and a thickness ranging from 30 nm to 39 nm or 50 nm to 55 nm.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An extreme ultraviolet mask, comprising an absorber having an index of refraction ranging from 0.87 to 1.02, an extinction coefficient ranging from 0.065 to 0.085, and a thickness ranging from 33.5 nm to 43.5 nm.

2. The extreme ultraviolet mask of claim 1, wherein the absorber has the index of refraction ranging from 0.90 to 1.00.

3. The extreme ultraviolet mask of claim 1, wherein the absorber has the index of refraction of 0.95.

4. The extreme ultraviolet mask of claim 1, wherein the absorber has the extinction coefficient ranging from 0.070 to 0.080.

5. The extreme ultraviolet mask of claim 1, wherein the absorber has the extinction coefficient of 0.075.

6. The extreme ultraviolet mask of claim 1, wherein the absorber has the thickness ranging from 35.5 nm to 39.5 nm.

7. The extreme ultraviolet mask of claim 1, wherein the absorber has the thickness of 38.5 nm.

8. The extreme ultraviolet mask of claim 1, wherein the absorber comprises a material selected from the group consisting of Sn, Ni, Te, and an alloy of two or more of Sn, Ni, and Te.

9. An extreme ultraviolet mask, comprising an absorber having an index of refraction ranging from 0.87 to 1.02, an extinction coefficient ranging from 0.085 to 0.105, and a thickness ranging from 25.5 nm to 35.5 nm.

10. The extreme ultraviolet mask of claim 9, wherein the absorber has the index of refraction ranging from 0.90 to 1.00.

11. The extreme ultraviolet mask of claim 9, wherein the absorber has the index of refraction of 0.95.

12. The extreme ultraviolet mask of claim 9, wherein the absorber has the extinction coefficient ranging from 0.090 to about 0.100.

13. The extreme ultraviolet mask of claim 9, wherein the absorber has the extinction coefficient of 0.095.

14. The extreme ultraviolet mask of claim 9, wherein the absorber has the thickness ranging from 27.5 nm to 31.5 nm.

15. The extreme ultraviolet mask of claim 9, wherein the absorber has the thickness of 30.5 nm.

16. An extreme ultraviolet mask, including an absorber having an index of refraction ranging from 0.895 to 0.950, an extinction coefficient ranging from 0.0600 to 0.0610, and a thickness ranging from 50 nm to 55 nm.

17. The extreme ultraviolet mask of claim 16, wherein the absorber has the index of refraction ranging from 0.944 to 0.945.

18. The extreme ultraviolet mask of claim 16, wherein the absorber has the index of refraction ranging from 0.900 to 0.902.

19. The extreme ultraviolet mask of claim 16, wherein the absorber has the index of refraction ranging from 0.90 to 0.945, and the extinction coefficient of 0.0605.

20. The extreme ultraviolet mask of claim 16, wherein the absorber has the index of refraction of 0.9445, and the thickness of 53 nm.
